(19) United States
(12) Patent Application Publication
(10) Pub. No.: US 2013/0065403 A1
(43) Pub. Date: Mar. 14, 2013

(54) WAFER CARRIER WITH THERMAL FEATURES

(71) Applicants: Ajit Paranjpe, Basking Ridge, NJ (US); Boris Volf, Hillsborough, NJ (US); Eric A. Armour, Pennington, NJ (US); Sandeep Krishnan, Princeton, NJ (US); Guanghua Wei, Dayton, NJ (US); Lukas Urban, Princeton, NJ (US)

(72) Inventors: Ajit Paranjpe, Basking Ridge, NJ (US); Boris Volf, Hillsborough, NJ (US); Eric A. Armour, Pennington, NJ (US); Sandeep Krishnan, Princeton, NJ (US); Guanghua Wei, Dayton, NJ (US); Lukas Urban, Princeton, NJ (US)

(21) Appl. No.: 13/673,340

(22) Filed: Nov. 9, 2012

Related U.S. Application Data
(63) Continuation of application No. 13/598,122, filed on Aug. 29, 2012.
(60) Provisional application No. 61/529,988, filed on Sep. 1, 2011.

(51) Int. Cl. B65D 85/00; H01L 21/302

(52) U.S. Cl. 438/758; 118/725; 206/711; 257/E21.214

(57) ABSTRACT

A wafer carrier used in wafer treatments such as chemical vapor deposition has pockets for holding the wafers and support surfaces for supporting the wafers above the floors of the pockets. The carrier is provided with thermal control features such as trenches which form thermal barriers having lower thermal conductivity than surrounding portions of the carrier. These thermal control features promote a more uniform temperature distribution across the wafer surfaces and across the carrier top surface.

### CROSS-REFERENCE TO RELATED APPLICATIONS

The present application is a continuation of U.S. patent application Ser. No. 13/598,122, filed Aug. 29, 2012, which claims the benefit of the filing date of U.S. Provisional Patent Application No. 61/529,988, filed Sep. 1, 2011, the disclosures of which are hereby incorporated herein by reference.

### BACKGROUND OF THE INVENTION

The present invention relates to wafer processing apparatus, to wafer carriers for use in such processing apparatus, and to methods of wafer processing.

Many semiconductor devices are formed by epitaxial growth of a semiconductor material on a substrate. The substrate typically is a crystalline material in the form of a disc, commonly referred to as a “wafer.” For example, devices formed from compound semiconductors such as III-V semiconductors typically are formed by growing successive layers of the compound semiconductor using metal organic chemical vapor deposition or “MOCVD.” In this process, the wafers are exposed to a combination of gases, typically including a metal organic compound and a source of a group V element which flow over the surface of the wafer while the wafer is maintained at an elevated temperature. One example of a III-V semiconductor is gallium nitride, which can be formed by reaction of an organo-gallium compound and ammonia on a substrate having a suitable crystal lattice spacing, as for example, a sapphire wafer. Typically, the wafer is maintained at a temperature on the order of 500-1200° C. during deposition of gallium nitride and related compounds.

Composite devices can be fabricated by depositing numerous layers in succession on the surface of the wafer under slightly different reaction conditions, as for example, additions of other group III or group V elements to vary the crystal structure and bandgap of the semiconductor. For example, in a gallium nitride based semiconductor, indium, aluminum or both can be used in varying proportion to vary the bandgap of the semiconductor. Also, p-type or n-type dopants can be added to control the conductivity of each layer. After all of the semiconductor layers have been formed and, typically, after appropriate electric contacts have been applied, the wafer is cut into individual devices. Devices such as light-emitting diodes (“LEDs”), lasers, and other electronic and optoelectronic devices can be fabricated in this way.

In a typical chemical vapor deposition process, numerous wafers are held on a device commonly referred to as a wafer carrier so that a top surface of each wafer is exposed at the top surface of the wafer carrier. The wafer carrier is then placed into a reaction chamber and maintained at the desired temperature while the gas mixture flows over the surface of the wafer carrier. It is important to maintain uniform conditions at all points on the top surfaces of the various wafers on the carrier during the process. Minor variations in composition of the reactive gases and in the temperature of the wafer surfaces cause undesired variations in the properties of the resulting semiconductor device. For example, if a gallium and indium nitride layer is deposited, variations in wafer surface temperature will cause variations in the composition and bandgap of the deposited layer. Because indium has a relatively high vapor pressure, the deposited layer will have a lower proportion of indium and a greater bandgap in those regions of the wafer where the surface temperature is higher. If the deposited layer is an active, light-emitting layer of an LED structure, the emission wavelength of the LEDs formed from the wafer will also vary. Thus, considerable effort has been devoted in the art heretofore towards maintaining uniform conditions.

One type of CVD apparatus which has been widely accepted in the industry uses a wafer carrier in the form of a large disc with numerous wafer-holding regions, each adapted to hold one wafer. The wafer carrier is supported on a spindle within the reaction chamber so that the top surface of the wafer carrier having the exposed surfaces of the wafers faces upwardly toward a gas distribution element. While the spindle is rotated, the gas is directed downwardly onto the top surface of the wafer carrier and flows across the top surface toward the periphery of the wafer carrier. The used gas is evacuated from the reaction chamber through ports disposed below the wafer carrier. The wafer carrier is maintained at the desired elevated temperature by heating elements, typically electrical resistive heating elements disposed below the bottom surface of the wafer carrier. These heating elements are maintained at a temperature above the desired temperature of the wafer surfaces, whereas the gas distribution element and the walls of the chamber typically are maintained at a temperature well below the desired reaction temperature so as to prevent premature reaction of the gases. Therefore, heat is transferred from the resistive heating element to the bottom surface of the wafer carrier and flows upwardly through the wafer carrier to the individual wafers. Heat is transferred from the wafers and wafer carrier to the gas distribution element and to the walls of the chamber.

Although considerable effort has been devoted in the art heretofore to design an optimization of such systems, still further improvement would be desirable. In particular, it would be desirable to provide better uniformity of temperature across the surface of each wafer, and better temperature uniformity across the entire wafer carrier.

### BRIEF SUMMARY OF THE INVENTION

One aspect of the present invention provides a wafer carrier comprising a body having oppositely-facing top and bottom surfaces extending in horizontal directions and a plurality of pockets open to the top surface, each such pocket being adapted to hold a wafer with a top surface of the wafer exposed at the top surface of the body, the carrier defining a vertical direction perpendicular to the horizontal directions. The wafer carrier body desirably includes one or more thermal control features such as trenches or other narrow gaps within carrier body. Each thermal control feature desirably extends along a defining surface within the body and has thermal conductivity different than a thermal conductivity of adjacent portions of the body. Most typically, the thermal conductivity of the thermal control feature is less than the thermal conductivity of adjacent portions of the body, so that the thermal control feature will retard thermal conduction in directions normal to the defining surface. For example, where the feature is a narrow trench unfilled by solid or liquid material, the trench has low thermal conductivity and retards thermal conduction across its width.

In a wafer carrier according to a further aspect of the invention, at least one thermal control feature is an oblique feature having at least a part of its defining surface oblique to the vertical direction.

A wafer carrier according to a further aspect of the invention also includes a body having oppositely-facing top and bottom surfaces extending in horizontal directions. The body defines a carrier central axis, a peripheral region, and a pocket region between the central axis and a plurality of pockets open to the top surface in the pocket region, each such pocket being adapted to hold a wafer with a top surface of the wafer exposed at the top surface of the body. In the wafer carrier according to this aspect of the invention, the body most preferably includes a peripheral thermal control feature extending around the pocket region between the pocket region and the peripheral region, the peripheral thermal control feature having lower thermal conductivity than adjacent portions of the body so that the peripheral thermal control feature reduces thermal conduction between the pocket region and the peripheral region.

A wafer carrier according to another aspect of the invention includes a body having oppositely-facing top and bottom surfaces extending in horizontal directions, a carrier central axis, a peripheral surface, and a plurality of pockets open to the top surface between the central axis and the peripheral surface. Each such pocket may be adapted to hold a wafer with a top surface of the wafer exposed at the top surface of the body. The body may have a plurality of pocket thermal control features. Each pocket may have a pocket thermal control feature associated with the pocket extending at least partially around a portion of the body disposed beneath the pocket. The body may also have a peripheral thermal control feature extending around the carrier adjacent the peripheral surface. The thermal control features may have lower thermal conductivity than adjacent portions of the body so that the thermal control features suppress thermal conduction in the horizontal directions.

Still further aspects of the invention include wafer processing apparatus incorporating the wafer carriers as discussed above, and methods of processing wafers using such carriers.

### BRIEF DESCRIPTION OF THE DRAWINGS

FIG. 1 is a simplified, schematic sectional view depicting chemical vapor deposition apparatus in accordance with one embodiment of the invention.

FIG. 2 is a diagrammatic top plan view of a wafer carrier used in the apparatus of FIG. 1.

FIG. 3 is a fragmentary, diagrammatic sectional view taken along line 3-3 in FIG. 2, depicting the wafer carrier in conjunction with a wafer.

FIGS. 4, 5, and 6 are fragmentary, diagrammatic sectional views depicting portion of a wafer carriers in accordance with further embodiments of the invention.

FIG. 7 is a fragmentary, diagrammatic sectional view depicting a portion of a wafer carrier according to a further embodiment of the invention.

FIG. 8 is a view similar to FIG. 9 but depicting a portion of a conventional wafer carrier.

FIG. 9 is a graph depicting temperature distributions during operation of the wafer carriers of FIGS. 7 and 8.

FIGS. 10-16 are fragmentary, diagrammatic sectional views depicting portions of wafer carriers according to further embodiments of the invention.

FIGS. 17 and 18 are fragmentary, diagrammatic top plan views depicting portions of wafer carriers according to still further embodiments of the invention.

FIGS. 19-24 are fragmentary, diagrammatic sectional views depicting portions of wafer carriers according to other embodiments of the invention.

FIG. 25 is a diagrammatic bottom plan view of a wafer carrier according to another embodiment of the invention.

FIG. 26 is an enlarged, fragmentary, diagrammatic bottom plan view depicting a portion of the wafer carrier of FIG. 25.

FIG. 27 is a fragmentary, diagrammatic sectional view taken along line 27-27 in FIG. 25.

FIGS. 28 and 29 are fragmentary, diagrammatic bottom plan views depicting portions of wafer carriers according to still further embodiments of the invention.

FIG. 30 is an enlarged, fragmentary, diagrammatic bottom plan view depicting a portion of the wafer carrier of FIG. 29.

FIG. 31 is a fragmentary, diagrammatic bottom plan view depicting a portion of a wafer carrier according to yet another embodiment of the invention.

FIG. 32 is a diagrammatic bottom plan view of a wafer carrier according to still another embodiment of the invention.

### DETAILED DESCRIPTION

Chemical vapor deposition apparatus in accordance with one embodiment of the invention includes a reaction chamber 10 having a gas distribution element 12 arranged at one end of the chamber. The end having the gas distribution element 12 is referred to herein as the “top” end of the chamber 10. This end of the chamber typically, but not necessarily, is disposed at the top of the chamber in the normal gravitational frame of reference. Thus, the downward direction as used herein refers to the direction away from the gas distribution element 12 and the upward direction refers to the direction within the chamber, toward the gas distribution element 12, regardless of whether these directions are aligned with the gravitational upward and downward directions. Similarly, the “top” and “bottom” surfaces of elements are described herein with reference to the frame of reference of chamber 10 and element 12.

Gas distribution element 12 is connected to sources 14 of gases to be used in the CVD process, such as a carrier gas and reactant gases such as a source of a group III metal, typically a metalorganic compound, and a source of a group V element as, for example, ammonia or other group V hydride. The gas distribution element is arranged to receive the various gases and direct a flow of gasses generally in the downward direction. The gas distribution element 12 desirably is also connected to a coolant system 16 arranged to circulate a liquid through the gas distribution element so as to maintain the temperature of the element at a desired temperature during operation. The coolant system 16 is also arranged to circulate liquid through the wall of chamber 10 so as to maintain the wall at a desired temperature. Chamber 10 is also equipped with an exhaust system 18 arranged to remove spent gases from the interior of the chamber through ports (not shown) at or near the bottom of the chamber so as to permit continuous flow of gas in the downward direction from the gas distribution element.

A spindle 20 is arranged within the chamber so that the central axis 22 of the spindle extends in the upward and downward directions. The spindle has a fitting 24 at its top end, i.e., at the end of the spindle closest to the gas distribution element 12. In the particular embodiment depicted, the fitting 24 is a generally conical element. Spindle 20 is connected to a rotary drive mechanism 26 such as an electric motor drive, which is arranged to rotate the spindle about axis 22. A heating element 28 is mounted within the chamber and surrounds spindle 20 below fitting 24. The chamber is also provided with an openable port 30 for insertion and removal of wafer carriers. The foregoing elements may be of conventional construction. For example, suitable reaction chambers are sold commercially under the registered trademark TURBODISC by Veeco Instruments, Inc. of Plainview, N.Y., USA, assignee of the present application.

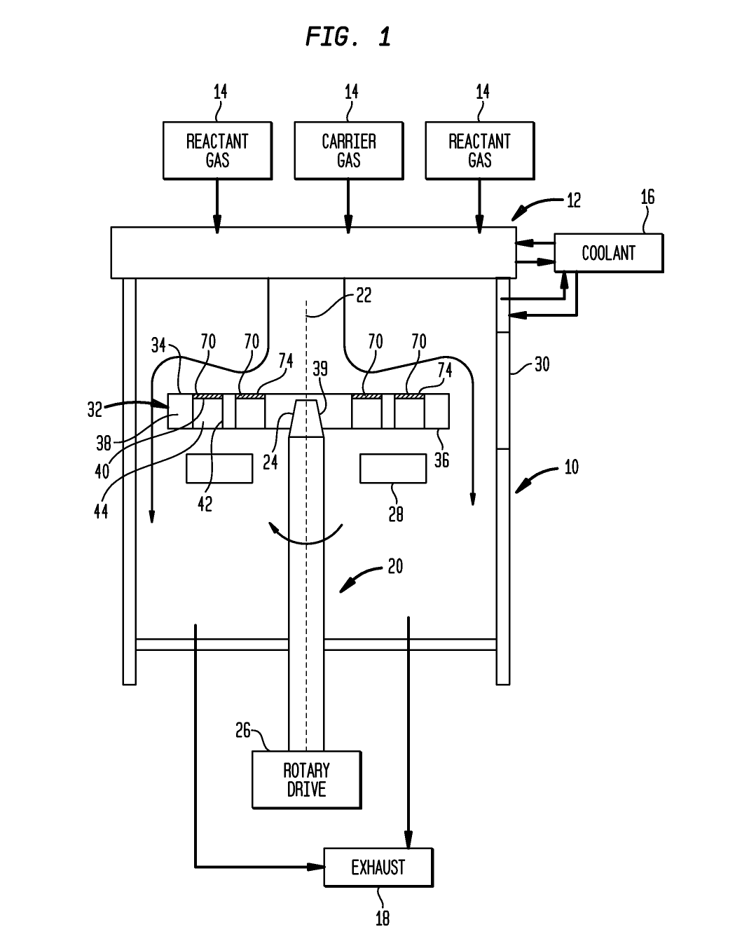

In the operative condition depicted in FIG. 1, a wafer carrier 32 is mounted on the fitting 24 of the spindle. The wafer carrier has a structure which includes a body generally in the form of a circular disc having a central axis 25 extending perpendicular to the top and bottom surfaces. The body of the wafer carrier has a first major surface, referred to herein as the “top” surface 34, and a second major surface, referred to herein as the “bottom” surface 36. The structure of the wafer carrier also has a fitting 39 arranged to engage the fitting 24 of the spindle and to hold the body of the wafer carrier on the spindle with the top surface 34 facing upwardly toward the gas distribution element 12, with the bottom surface 36 facing downwardly toward heating element 28 and away from the gas distribution element. Merely by way of example, the wafer carrier body may be about 465 mm in diameter, and the thickness of the carrier between top surface 34 and bottom surface 32 may be on the order of 15.9 mm. In the particular embodiment illustrated, the fitting 39 is formed as a frustoconical depression in the bottom surface of the body 32. However, as described in copending, commonly assigned US Patent Publication No. 2009-0155028 A1, the disclosure of which is hereby incorporated by reference herein, the structure of the wafer carrier may include a hub formed separately from the body and the fitting may be incorporated in such a hub. Also, the configuration of the fitting will depend on the configuration of the spindle.

The body desirably includes a main portion 38 formed as a monolithic slab of a non-metallic refractory first material as, for example, a material selected from the group consisting of silicon carbide, boron nitride, boron carbide, aluminum nitride, alumina, sapphire, quartz, graphite, and combinations thereof, with or without a refractory coating as, for example, a carbide, nitride or oxide.

The body of the wafer carrier has a central region 27 at and near the central axis 25, a pocket or wafer-holding region 29 encircling the central region and a peripheral region 31 encircling the pocket region and defining the periphery of the body. The peripheral region 31 defines a peripheral surface 33 extending between the top surface 34 and bottom surface 36 at the outermost extremity of the body.

The body of the carrier defines a plurality of circular pockets 40 open to the top surface in the pocket region 29. As best seen in FIGS. 1 and 3, the main portion 38 of the body defines a substantially planar top surface 34. The main portion 38 has holes 42 extending through the main portion, from the top surface 34 to the bottom surface 36. A minor portion 44 is disposed within each hole 42. The minor portion 44 disposed within each hole defines a floor surface 46 of the pocket 40, the floor surface being recessed below the top surface 34. The minor portions 44 are formed from a second material, preferably a non-metallic refractory material consisting of silicon carbide, boron nitride, boron carbide, aluminum nitride, alumina, sapphire, quartz, graphite, and combinations thereof, with or without a refractory coating as, for example, a carbide, nitride or oxide. The second material desirably is different from the first material constituting the main portion. The second material may have a thermal conductivity higher than the thermal conductivity of the first material. For example, where the main portion is formed from graphite, the minor portions may be formed from silicon carbide. The minor portions 44 and the main portion 38 cooperatively define the bottom surface 36 of the body. In the particular embodiment depicted in FIG. 3, the bottom surface of the main portion 38 is planar, and the bottom surfaces of the minor portions 44 are coplanar with the bottom surface of the main portion, so that the bottom surface 36 is planar.

The minor portions 44 are frictionally engaged with the walls of the holes 42. For example, the minor portions may be press-fit into the holes or shrink-fitted by raising the main portion to an elevated temperature and inserting cold minor portions into the holes. Desirably, all of the pockets are of uniform depth. This uniformity can be achieved readily by forming all of the minor portions to a uniform thickness as, for example, by grinding or polishing the minor portions.

There is a thermal barrier 48 between each minor portion 44 and the surrounding material of the main portion 38. The thermal barrier is a region having thermal conductivity that is lower than the thermal conductivity of the bulk material of the main portion. In the particular embodiment depicted in FIG. 3, the thermal barrier includes a macroscopic gap 48, as, for example, a gap about 100 microns or more thick, formed by a groove in the wall of the main portion 38 defining the hole 42. This gap contains a gas such as air or the process gasses encountered during operation, and hence has much lower thermal conductivity than the neighboring solid materials.

The abutting surfaces of the minor portions 44 and main portion 38 also define parts of the thermal barrier. Although these surfaces abut one another on a macroscopic scale, neither surface is perfectly smooth. Therefore, there will be microscopic, gas-filled gaps between parts of the abutting surfaces. These gaps will also impede thermal conduction between the minor portion 44 and main portion 38.

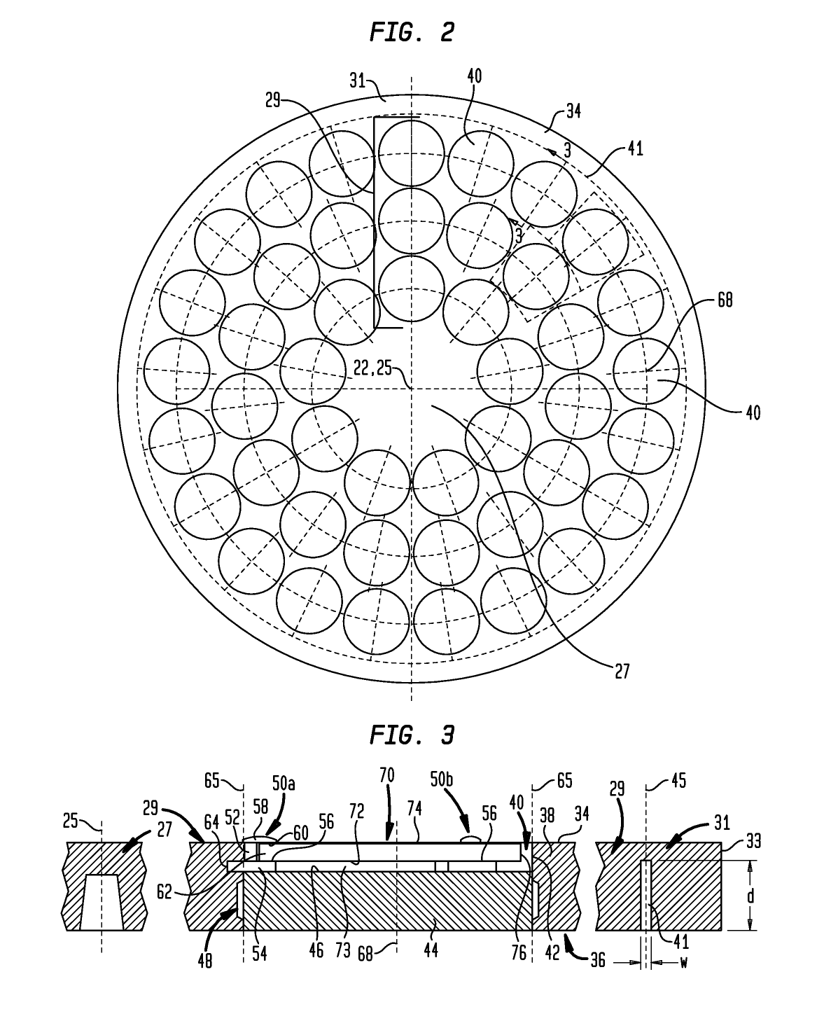

As best appreciated with reference to FIGS. 2 and 3, each pocket 40 has a pocket axis 68 which extends in the vertical direction, perpendicular to the top and bottom surfaces 34, 36 and parallel to the central axis 25 of the wafer carrier. The thermal barrier 48 associated with each pocket extends entirely around the pocket axis 68 of that pocket in alignment with the periphery of the pocket. In this embodiment each thermal barrier 48 extends along a theoretical defining surface 65 in the form of a right circular cylinder coaxial with the pocket axis 68 and having a radius equal to or nearly equal to the radius of the pocket 40. The features forming the thermal barrier 48, such as the gap 38 and the abutting surfaces of the minor portion 44 and main portion 38 have dimensions in the directions along the defining surface which are much greater than the dimensions of these features in the directions perpendicular to the defining surface. The thermal conductivity of the thermal barrier 48 is less than the thermal conductivity of the adjacent portions of the body, i.e., less than the thermal conductivity of the main portion 38 and minor portion 44. Thus, the thermal barrier 48 retards thermal conductivity in the directions normal to the defining surface, i.e., the horizontal directions parallel to the top and bottom surfaces 34, 36.

The wafer carrier according to this embodiment of the invention further includes a peripheral thermal control feature or thermal barrier 41 disposed between the pocket region 29 and the peripheral region 31 of the carrier body. In this embodiment, the peripheral thermal barrier 41 is a trench extending into the main portion 38 of the body. As used in this disclosure with reference to a feature of a wafer carrier, the term “trench” means a gap within the wafer carrier which extends to a surface of the wafer carrier and which has a depth substantially greater than its width. In this embodiment, the trench 41 is formed within a single, unitary element, namely the main portion 38 of the body. Also, in this embodiment trench 41 is not filled by any solid or liquid material, and thus will be filled with the surrounding atmosphere, as, for example, air when the carrier is outside of the chamber or process gasses when the carrier is within the chamber. The trench extends along a defining surface 45 which is in the form of a surface of revolution about axis 25, in this case a right circular cylinder concentric with the central axis 25 of the wafer carrier. In the case of a trench, the defining surface can be taken as the surface equidistant from the walls of the trench. Stated another way, the depth dimension d of trench 43 is perpendicular to the top and bottom surfaces of the wafer carrier and parallel to the central axis of the wafer carrier. Trench 41 has widthwise dimensions w perpendicular to surface 45 which are smaller than the dimensions of the trench parallel to the defining surface.

The carrier further includes locks 50 associated with the pockets. The locks may be configured as discussed in greater detail in U.S. patent application Ser. No. 12/855,739, filed Aug. 13, 2010, and in the corresponding International Application No. PCT/US2011/046567, filed Aug. 4, 2011, the disclosures of which are incorporated by reference herein. Locks 50 are optional and may be omitted; other carriers discussed below in this disclosure omit the locks. The locks 50 preferably are formed from a refractory material having thermal conductivity which is lower than the conductivity of the minor portions 44 and preferably lower than the conductivity of the main portion 38. For example, the locks may be formed from quartz. Each lock includes a middle portion 52 (FIG. 3) in the form of a vertical cylindrical shaft and a bottom portion 54 in the form of a circular disc. The bottom portion 54 of each lock defines an upwardly-facing support surface 56. Each lock further includes a top portion 58 projecting transverse to the axis of the middle portion. The top portion is not symmetrical about the axis of the middle portion 52. The top portion 58 of each lock defines a downwardly-facing lock surface 60 overlying the support surface 56 of the lock but spaced apart from the support surface. Thus, each lock defines a gap 62 between surfaces 56 and 60. Each lock is secured to the wafer carrier so that the lock can be moved between the operative position shown in FIG. 3, in which the top portion 58 of the lock projects over the pocket, and an inoperative position in which the top portion does not project over the pocket.

In operation, the carrier is loaded with circular, disc-like wafers 70. With one or more of the locks 50 associated with each pocket in its inoperative position, the wafer is placed into the pocket so that a bottom surface 72 of the wafer rests on the support surfaces 56 of the locks. The support surfaces of the locks cooperatively support the bottom surface 72 of the wafer above the floor surface 46 of the pocket, so that there is a gap 73 (FIG. 3) between the bottom surface of the wafer and the floor surface of the pocket, and so that the top surface 74 of the wafer is coplanar or nearly coplanar with the top surface 34 of the carrier. The dimensions of the carrier, including the locks, are selected so that there is a very small clearance between the edge or peripheral surface 76 of the wafer and the middle portions 52 of the locks. The middle portions of the locks thus center the wafer within the pocket, so that the distance between the edge of the wafer and the wall of the pocket is substantially uniform around the periphery of the wafer.

The locks are brought to the operative positions, so that the top portion 58 of each lock, and the downwardly facing lock surface 60 (FIG. 3) projects inwardly over the pocket and hence over the top surface 74 of the wafer. The lock surfaces 60 are disposed at a vertical level higher than the support surfaces 56. Thus, the wafer is engaged between the support surfaces 56 and the lock surfaces, and constrained against upward or downward movement relative to the carrier. The top and bottom elements of the locks desirably are as small as practicable, so that these elements contact only very small parts of the wafer surfaces adjacent the periphery of each wafer. For example, the lock surfaces and support surfaces may engage only a few square millimeters of the wafer surfaces.

Typically, the wafers are loaded onto the carrier while the carrier is outside of the reaction chamber. The carrier, with the wafers thereon, is loaded into the reaction chamber using conventional robotic apparatus (not shown), so that the fitting 39 of the carrier is engaged with the fitting 24 of the spindle, and the central axis 25 of the carrier is coincident with the axis 22 of the spindle. The spindle and carrier are rotated about this common axis. Depending on the particular process employed, such rotation may be at hundreds of revolutions per minute or more.

The gas sources 14 are actuated to supply process gasses and carrier gasses to the gas distribution element 12, so that these gasses flow downwardly toward the wafer carrier and wafers, and flow generally radially outwardly over the top surface 34 of the carrier and over the exposed top surfaces 74 of the wafers. The gas distribution element 12 and the walls of chamber 10 are maintained at relatively low temperatures to inhibit reaction of the gasses at these surfaces.

Heater 28 is actuated to heat the carrier and the wafers to the desired process temperature, which may be on the order of 500 to 1200° C. for certain chemical vapor deposition processes. Heat is transferred from the heater to the bottom surface 36 of the carrier body principally by radiant heat transfer. The heat flows upwardly by conduction through the main portion 38 of the carrier body to the top surface 34 of the body. Heat also flows upwardly through the minor portions 44 of the wafer carrier, across the gaps 73 between the floor surfaces of the pockets and the bottom surfaces of the wafers, and through the wafers to the top surfaces 74 of the wafers. Heat is transferred from the top surfaces of the body and wafers to the walls of chamber 10 and to the gas distribution element 12 by radiation, as well as from the peripheral surface 33 of the wafer carrier to the wall of the chamber. Heat and is also transferred from the wafer carrier and wafers to the process gasses.

The process gasses react at the top surfaces of the wafers to treat the wafers. For example, in a chemical vapor deposition processes, the process gasses form a deposit on the wafer top surfaces. Typically, the wafers are formed from a crystalline material, and the deposition process is epitaxial deposition of a crystalline material having lattice spacing similar to that of the material of the wafer.

For process uniformity, the temperature of the top surface of each wafer should be constant over the entire top surface of the wafer, and equal to the temperature of the other wafers on the carrier. To accomplish this, the temperature of the top surface of 74 of each wafer should be equal to the temperature of the carrier top surface 34. The temperature of the carrier top surface depends on the rate of heat transfer through the main portion 38 of the body, whereas the temperature of the wafer top surface depends on the rate of heat transfer through the minor portion 44, the gap 73 and the wafer itself. The high thermal conductivity, and resulting low thermal resistance, of the minor portions 44 compensates for the high thermal resistance of the gaps 73, so that the wafer top surfaces are maintained at temperatures substantially equal to the temperature of the carrier top surface. This minimizes heat transfer between the edges of the wafers and the surrounding portions of the carrier and thus helps to maintain a uniform temperature over the entire top surface of each wafer. To provide this effect, the floor surfaces of the pockets 46 must be at a higher temperature than the adjacent parts of the main portion 38. The thermal barriers 48 between the minor portions 44 and the main portion 38 of the body minimize thermal conduction between the minor portions 44 and the main portion 38 in horizontal directions, and thus minimize heat loss from the minor portions 44 to the main portion. This helps to maintain this temperature differential between the floor surface of the pockets and the carrier top surface. Moreover, the reduction in horizontal heat transfer in the carrier at the periphery of the pocket also helps to reduce localized heating of the carrier top surface immediately surrounding the pocket. As further discussed below, those portions of the carrier top surface immediately surrounding the pocket tend to run hotter than other portions of the carrier top surface. By reducing this effect, the thermal barriers promote more uniform deposition.

Because the peripheral portion 31 of the wafer carrier body is disposed close to the wall of chamber 10, the peripheral portion of the wafer carrier tends to transfer heat at a high rate to the wall of the chamber and therefore tends to run at a lower temperature than the rest of the wafer carrier. This tends to cool the portion of the carrier body near the outside of the pocket region 29, closest to the peripheral region. The peripheral thermal barrier 41 reduces horizontal heat transfer from the pocket region to the peripheral region, and thus reduces the cooling effect on the pocket region. This, in turn, reduces temperature differences within the pocket region. Although the peripheral thermal barrier will increase the temperature difference between the peripheral region 31 and the pocket region, this temperature difference does not adversely affect the process. The gas flows outwardly over the peripheral region, and thus the gas passing over the cool the peripheral region does not impinge on any of the wafers being processed. It has been the practice heretofore to compensate for heat transfer from the periphery of the wafer carrier to the wall of the chamber by making the heating element 28 (FIG. 1) non-uniform, so that more heat is transferred to the peripheral region and to the outer portion of the pocket region. This approach can be used in conjunction with a peripheral thermal barrier as shown. However, the peripheral thermal barrier reduces the need for such compensation.

As discussed in greater detail in the aforementioned U.S. patent application Ser. No. 12/855,739, filed Aug. 13, 2010,and in the corresponding International Application No. PCT/US2011/046567, filed Aug. 4, 2011, the locks 50 keep each wafer centered within the associated pocket and retain the edges of the wafer against upward movement due to bowing of the wafer. These effects promote more uniform heat transfer to the wafer.

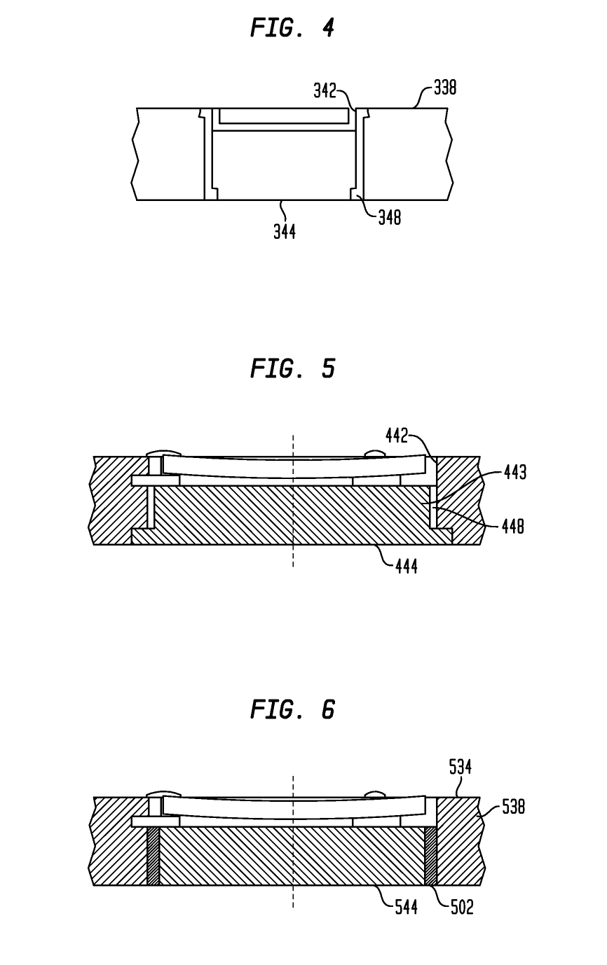

In a further variant (FIG. 4), minor portions 344 of the carrier body may be mounted to the main portion 338 by bushings 348 formed from quartz or another material having thermal conductivity lower than the conductivities of the main portion and minor portions. Here again, the minor portion desirably has higher thermal conductivity than the main portion. The bushing serves as part of the thermal barrier between the minor portion and main portion. The solid-to-solid interfaces between the bushing and minor portion, and between the bushing and main portion, provide additional thermal barriers. In this variant, the bushing defines the vertical wall 342 of the pocket.

The embodiment of FIG. 5 is similar to the embodiment discussed above with reference to FIGS. 1-3, except that each minor portion 444 includes a body 443 of smaller diameter than the corresponding hole 442 in the main portion 438, so that a gap 448 is provided as a thermal barrier. Each minor portion also includes a head 445 closely fitted in the main portion 438 to maintain concentricity of the minor portion and the hole 442.

The wafer carrier of FIG. 6 includes a main portion 538 and minor portions 544 similar to the carrier discussed above with reference to FIGS. 1-3. However, the carrier body of FIG. 6 includes ring-like border portions 502 encircling the minor portions and disposed between each minor portion and the main portion. The border portions 502 have thermal conductivity different from the thermal conductivity of the main portion and minor portions. As illustrated, the border portions are aligned beneath the periphery of each pocket. In a further variant, the border portions may be aligned beneath a part of the top surface 534 surrounding each pocket. The thermal conductivity of the border portions can be selected independently to counteract heat transfer to or from the edges of the wafers. For example, where those portions of the top surface 534 tend to be hotter than the wafer, the thermal conductivity of the border portions can be lower than the conductivity of the main portion.

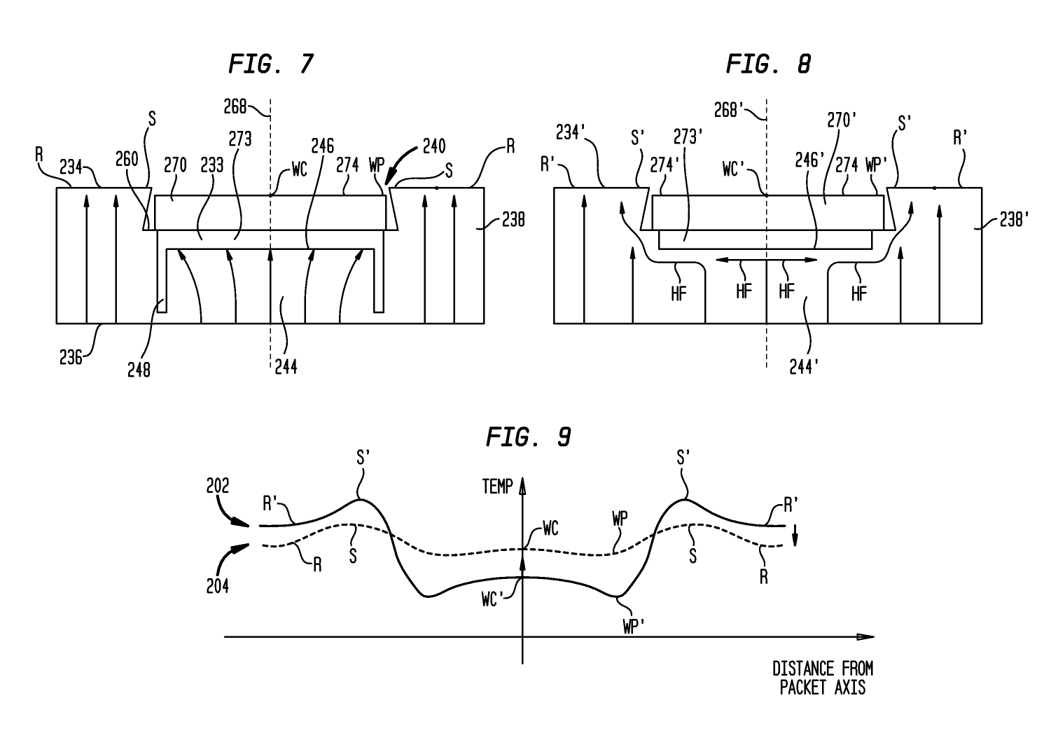

A wafer carrier according to a further embodiment of the invention, partially depicted in FIG. 7, has a body which includes a unitary main portion 238 of a refractory material defining the top surface 234 and bottom surface 236 of the body. The main portion defines pockets 240 formed in the top surface of the body. Each pocket has a floor surface 246, as well as a circumferential wall surface surrounding the pocket 240 and an upwardly-facing wafer support surface 260 extending around the pocket at a vertical level higher than the floor surface 246. The pocket is generally symmetrical about a vertical pocket axis 268. A thermal barrier 248 in the form of a trench extends around the axis 268 beneath the periphery of the pocket. In this embodiment, trench 248 is open to the top surface 234 of the carrier body; it intersects the wafer support surface 260 which constitutes a part of the top surface. Trench 248 has a defining surface in the form of a right circular cylinder concentric with pocket axis 248. Trench 248 extends downwardly from the pocket floor surface 246 almost all the way to the bottom surface 236 of the wafer carrier, but stops short of the bottom surface. The trench substantially surrounds a minor portion 244 of the carrier body defining the pocket floor surface 246.

During operation, trench 248 suppresses heat conduction in horizontal directions. Although the minor portion 244 and main portion 238 are formed integrally with one another, there are still temperature differences between the minor portion and the main portion, and still a need to suppress horizontal heat conduction. This need can be understood with reference to FIG. 8, depicting a conventional wafer carrier similar to the carrier of FIG. 7 but without the thermal barrier. When a wafer 270′ is disposed in the pocket, there will be a gap 273′ between the wafer and the pocket floor surface 246′. The gas within gap 273 has substantially lower thermal conductivity than the material of the wafer carrier, and thus insulates the minor portion from the wafer. During operation, heat is conducted upwardly through the wafer carrier and lost to the surroundings from the top surface 234′ of the carrier and from the wafer top surface 274′. The gap acts as an insulator which blocks vertical heat flow from the carrier portion 244′ underlying the wafer to the wafer. This means that at the level of floor surface 246′, portion 244′ will be hotter than the immediately adjacent parts of main portion 238′. Thus, heat will flow horizontally from portion 244′ to portion 238′ as indicated schematically by arrows HF in FIG. 8. This raises the temperature of the parts of main portion 238 immediately surrounding the pocket, so that a portion S′ of the top surface 234′ immediately surrounding the pocket is hotter than other portions R′ of top surface 234′ remote from the pocket. Moreover, the horizontal heat flow tends to cool the pocket floor surface 246′. The cooling is uneven, so that portions of the pocket floor surface near the pocket axis 268′ are hotter than portions remote from the axis. Because of the insulating effect of gap 273′, the wafer top surface 274′ will be cooler than the carrier top surface 234. Cooling of the pocket floor surface 246′ due to horizontal heat conduction exacerbates this effect. Moreover, the uneven cooling of the pocket floor surface results in an uneven temperature on wafer top surface 274′, with the center of the wafer top surface WC′ hotter than the periphery WP′ of the wafer top surface.

These effects are depicted in the solid-line curve 202 of FIG. 9, which is a plot of the top surface temperatures of the wafer top surface versus distance from the pocket axis. Again, the wafer top surface (points WC′ and WP′) is substantially cooler that the carrier top surface (points R′ and S′), and there is a significant temperature difference between points WC′ and WP′. Point S′ is hotter than point R′. These temperature differences reduce process uniformity.

In the wafer carrier of FIG. 7, thermal barrier 248 suppresses these effects. Because horizontal heat conduction from minor portion 244 is blocked, the floor surface 246 and hence the wafer top surface 274 are hotter and more nearly uniform in temperature. As shown by broken-line curve 204 in FIG. 9, the temperature of points WC and WP are nearly equal, and are close to the temperature of the carrier top surface at points R and S. Also, the temperature at point S, near the pocket, is close to the temperature at point R, remote from the pocket.

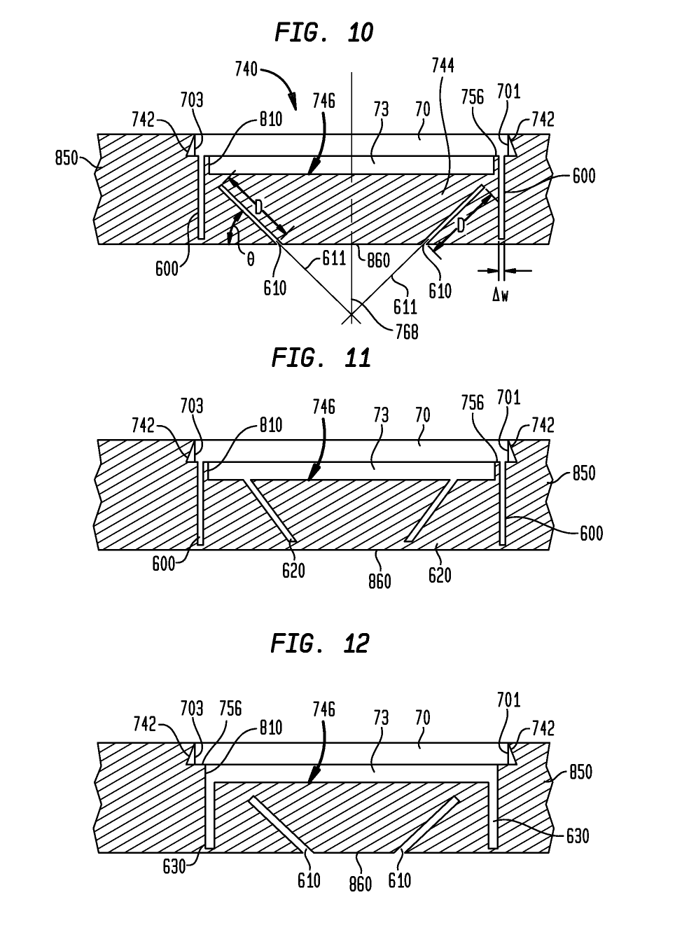

A wafer carrier according to a further embodiment includes a unitary body 850 defining a plurality of pockets 740, only one of which is shown in FIG. 10. Each pocket 740 has a support surface 756 disposed above the floor surface 746 and an undercut peripheral wall 742 surrounding the pocket. The pocket has an outer thermal barrier or trench 600 extending around the pocket axis 768 near the periphery of the pocket. Trench 600 is similar to the trench 248 discussed above with reference to FIG. 7. As in the carrier of FIG. 7, trench 600 is open to the top of the wafer carrier but does not extend through the wall of the wafer carrier bottom 860. Trench 600 intersects support surface 756 between peripheral wall 742 and wall 810 which forms the inner edge of the support surface. Here again, trench 600 is substantially vertical and generally in the form of a right circular cylinder concentric with the axis 768 of pocket 740. Merely by way of example, the width Aw of trench 600 can be a variety of values, including for example, about 0.5 to about 10,000 microns, about to 1 to about 7,000 microns, about 1 to about 5,000 microns, about 1 to about 3,000 microns, about 1 to about 1,000 microns, or about 1 to about 500 microns. The selected width Aw of a particular trench 600 in a particular wafer carrier design can vary, depending upon the anticipated wafer processing conditions, the recipes for deposition of material onto the wafers to be held by the wafer carrier, and the anticipated heat profile of the wafer carrier during wafer processing.

The wafer carrier further includes an inner thermal barrier or trench 610 which extends around pocket axis 768 inside of the outer barrier or trench 600. Thus, trench 610 has a diameter which is less than that of pocket 40. Trench 610 intersects the bottom surface 860 of the wafer carrier so that the trench is open to the bottom of the wafer carrier but is not open to the top of the wafer carrier. Trench or thermal barrier 610 is an oblique thermal barrier having a defining surface which is oblique to the top and bottom surfaces of the trench. Stated another way, the depth dimension d of the trench lies at an oblique angle to the top and bottom surfaces of the wafer carrier. In the embodiment depicted, the defining surface 611 of trench 610 is generally in the form of a portion of a cone concentric with pocket axis 768, and the intersection between trench 610 and the bottom surface 860 is in the form of a circle concentric with the pocket axis. The angle Θ at which the defining surface of trench 610 intersects the bottom surface can range from about 3 degrees to about almost 90 degrees. Merely by way of example, the width Δw of trench 610 can be a variety of values, including for example, about 0.5 to about 10,000 microns, about to 1 to about 7,000 microns, about 1 to about 5,000 microns, about 1 to about 3,000 microns, about 1 to about 1,000 microns, or about 1 to about 500 microns. The selected width Δw of a particular trench 610 in a particular wafer carrier design can vary, depending upon the anticipated wafer processing conditions, the recipes for deposition of material onto the wafers to be held by the wafer carrier, and the anticipated heat profile of the wafer carrier during wafer processing.

The outer trench 600 functions in a manner similar to that discussed above to impede thermal conduction in horizontal directions between a portion 744 of the wafer carrier body underlying the wafer 70 and the remainder of body 850. The oblique thermal barrier or trench 610 impedes thermal conduction in horizontal directions and also impedes thermal conduction in the vertical direction. The balance of these two effects will depend on the angle Θ. Thus, trench 610 will reduce the temperature near the center of pocket floor surface 746 relative to other portions of the pocket floor, and thus will reduce the temperature at and near the center of the wafer top surface.

The wafer carrier of FIG. 11 is identical to that of FIG. 10 except that the inner, oblique trench 620 is open to the top of the wafer carrier and not to the bottom. Thus, trench 620 extends through the floor surface 746 of the pocket so that it communicates with gap 73. Trench 620 but does not extend through the bottom surface 860 of wafer carrier 850.

The wafer carrier of FIG. 12 is identical to the wafer carrier of FIG. 10 except that the outer trench 630 (FIG. 12) intersects the floor surface 746 of the pocket just inboard of the wafer support surface 756, so that one wall of the trench is continuous with the step surface 810 at the inside edge of the wafer support surface.

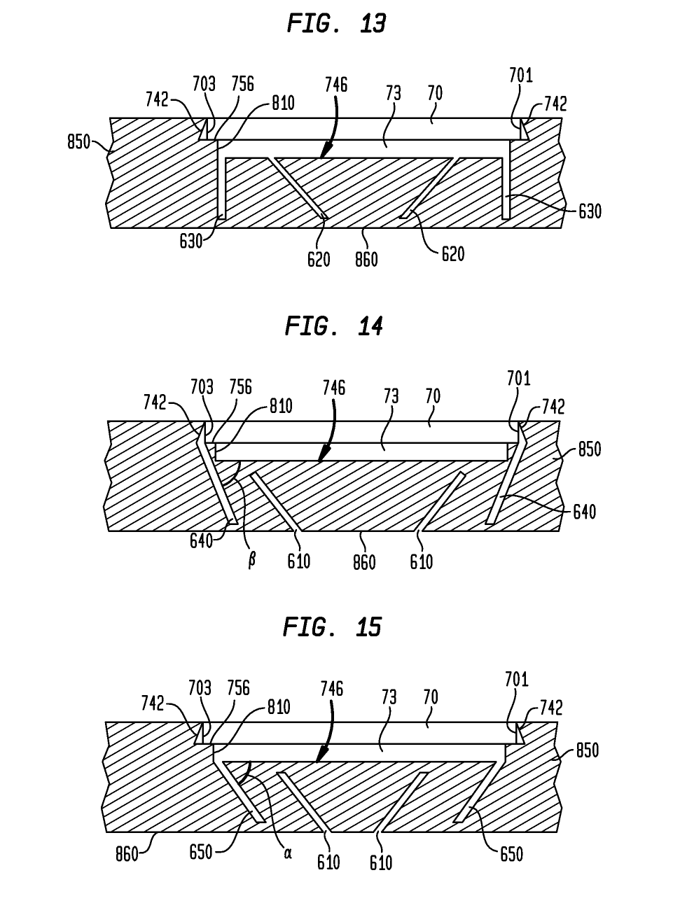

The wafer carrier of FIG. 13 is similar to the carrier of FIG. 12 except that the inner, oblique trench 620 extends is open to the top of the wafer carrier rather than the bottom. Trench 620 intersects the pocket floor surface 746 and is exposed to gap 73 but does not extend through the bottom surface 860 of wafer carrier 850.

The wafer carrier of FIG. 14 is similar to the carrier of FIG. 10, but has an outer trench 640 which is an oblique trench. The outer trench 640 intersects the wafer support surface 752 at or near the juncture of the wafer support surface 752 and the peripheral wall 742. The defining surface of trench 640 is in the form of a portion of a cone and extends at an angle β to the horizontal plane. Trench 640 does not intersect wafer carrier bottom 860. Angle β preferably is in the range from about 90 degrees to about 30 degrees.

The wafer carrier of FIG. 15 is also similar to the carrier of FIG. 10 but has an outer oblique trench 650 which intersects the pocket floor surface 746 and extends at an angle α to the horizontal plane. In this embodiment as well, the outer trench is open to the top of the wafer carrier but not the bottom. Thus, the trench communicates with gap 73 but does not extend through the bottom surface 860 of wafer carrier 850. Trench 650 is generally in the form of a portion of a cone concentric with the vertical axis of the pocket, and is disposed at an angle α to the horizontal plane. Angle α desirably is about 90 degrees to about 10 degrees, the smaller angle being limited by angular trench 650 not extending into angular trench 610.

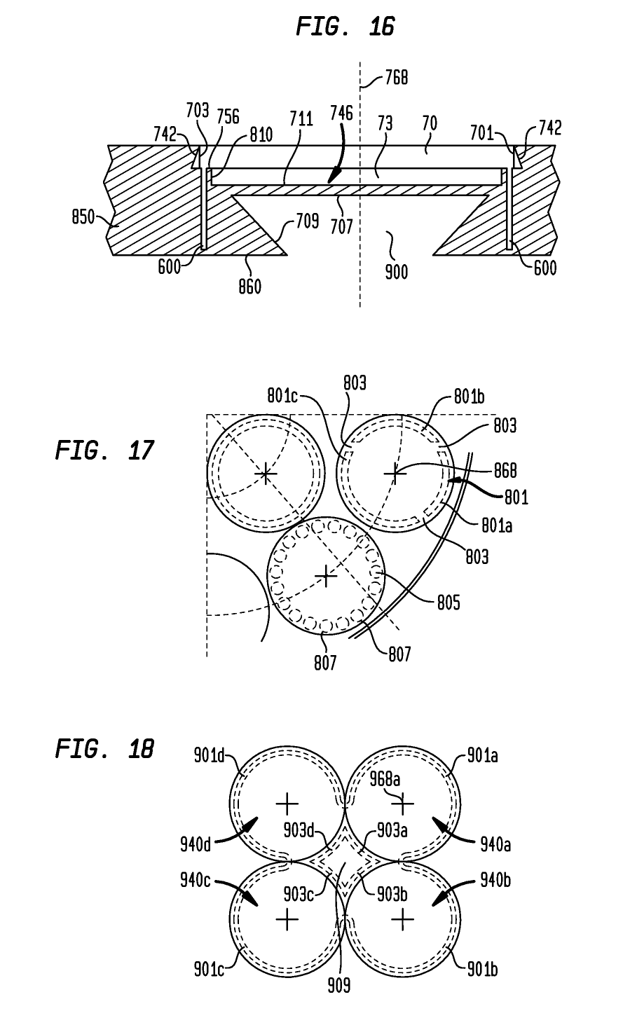

FIG. 16 shows another variation of the arrangement in FIG. 10 where a volume 900 is removed from the bottom of the wafer carrier in the region immediately surrounding the axis of the pocket. As disclosed in co-pending, commonly assigned US Patent Application Publication No. 2010-0055318, the disclosure of which is hereby incorporated by reference herein, the thermal conductance of the wafer carrier can be varied by varying its thickness. Thus, the relatively thin section 707 of the wafer carrier underlying the pocket floor surface 746 at the pocket axis 768 will have substantially greater thermal conductance than other sections of the wafer carrier. Because heat is transferred to the bottom of the wafer carrier primarily by radiation rather than conduction, the removed volume 900 does not appreciably insulate this portion of the wafer carrier. Thus, the center of the pocket floor surface will run at a higher temperature than other portions. The projecting edges 709 will tend to block radiation from sections 711, making the corresponding sections of floor surface 746 cooler. This arrangement can be used, for example, where the wafer tends to bow away from the floor surface 746 of the pocket at the center of the pocket. In this case, the thermal conductance of the gap 73 at the center of the pocket will be lower than the thermal conductance of the gap near the edge of the pocket. The uneven temperature distribution on the pocket floor surface will counteract the uneven conductance of the gap. The opposite effect can be obtained by selectively thickening the wafer carrier to reduce its conductance.

As discussed above with reference to FIG. 10, oblique trenches such as trench 610 (FIG. 10) reduce thermal conduction in the vertical direction, and thus can reduce the temperature of those portions of the wafer carrier surface overlying the oblique trenches, such as portions of the pocket floor surface. Thermal barriers other than trenches, such as the barrier 48 discussed above with reference to FIG. 3, can also be formed with defining surfaces which are oblique to the horizontal plane of the wafer carrier. Further, the wafer carrier can be provided with thermal features which locally increase thermal conductivity rather than decrease it. In the embodiments discussed above, the trenches and gaps are substantially devoid of any solid or liquid material, so that these trenches and gaps will be filled by gasses present in the surroundings, such as the process gasses in the chamber during operation. Such gasses have lower thermal conductivity than the solid material of the wafer carrier. However, the trenches or other gaps can be filled with nonmetallic refractory material such as silicon carbide, graphite, boron nitride, boron carbide, aluminum nitride, alumina, sapphire, quartz, and combinations thereof, with or without a refractory coating such as carbide, nitride, or oxide, or with refractory metals. If the solid filling is formed in the trenches or gaps so that the interfaces between the solid filling and the surrounding materials of the wafer carrier are free of gaps, and if the solid filling has higher conductivity than the surrounding material, the filled trenches or gaps will have greater thermal conductivity than the surrounding portions of the wafer carrier. In this case, the filled trenches or gaps will form features with enhanced conductance which act in the opposite way to the thermal barriers discussed above. The term “thermal control feature” as used in this disclosure includes both thermal barriers and features with enhanced conductance.

In the embodiments discussed above, the thermal control features associated with the pockets extend entirely around the pocket axis and are symmetrical about such axis, so that the defining surface of each thermal feature is a complete surface of revolution around the pocket axis, such as a cylinder or cone. However, the thermal control features may be asymmetrical, interrupted, or both. Thus, as shown in FIG. 17, a trench 801 includes three segments 801a, 801b and 801c each extending partially around the pocket axis 868. The segments are separated from one another by interruptions at locations 803. Another trench 805 is formed as a series of separate holes 807, so that the trench is interrupted between each pair of adjacent holes. Interruptions in the trenches help to preserve the mechanical integrity of the wafer carrier.

As seen in FIG. 18, a single trench 901a extends only partially around the pocket axis 968a of pocket 940a. This trench is continuous with trenches 901b, 901c and 901d associated with other pockets 940b, 940c and 940d, so that trenches 901a-901d form a single continuous trench extending around a group of four neighboring pockets. A further trench 903a disposed just outside the perimeter of pocket 940a extends partially around the pocket and joins with corresponding trenches of 903b-903d associated with the neighboring pockets. In further variants (not shown), a single continuous trench may extend around a group of two or three neighboring pockets, or may extend around a group of five or more neighboring pockets, depending upon the density of the pockets on the wafer carrier. The location of the continuous bridge between pockets can vary, as well as the length and width of the continuous trench. The continuous bridge can be formed, for example, from a continuous trench or series of separate holes (for example, holes 807 shown in FIG. 17).

The location of multiple pockets on the surface of the wafer carrier can affect the temperature distribution on the wafer carrier. For example, as shown in FIG. 18, pockets 940a-940d surround a small region 909 of the wafer top surface. As explained above in connection with FIG. 9, the insulating effect of the wafer and gap in each pocket tends to cause horizontal heat flow to neighboring regions of the carrier. Thus, region 909 would tend to run hotter than other regions of the carrier top surface. Trenches 903a-903d reduce this effect.

The thermal control features thus can be used as needed to control the temperature distribution over the surface of the carrier as a whole, as well as over the surface of the individual wafers. For example, due to the effects of neighboring pockets and wafers, the temperature distribution over the surface of an individual wafer may tend to be asymmetrical about the pocket axis. Thermal control features such as trenches which are asymmetrical about the pocket axis can counteract this tendency. Using the thermal control features discussed herein, any desired wafer temperature distribution in the radial and azimuthal directions around the axis of a pocket can be achieved.

The trenches need not be surfaces of revolution that generally follow the general outline of the pockets or of the support surfaces within the pockets. Thus, the trenches can be of any other geometry that achieves the desired temperature profile on the wafer. Such geometries include, for example, circles, ellipses, off-axis (or also called off-aligned) circles, off-axis ellipses, serpentines (both on axis and off-axis (or also called off-aligned)), spirals (both on axis and off-axis (or also called off-aligned)), clothoides (cornu spirals) (both on axis and off-axis (or also called off-aligned)), parabolas (both on axis and off-axis), rectangles (both on axis and off-axis), triangles (both on axis and off-axis (or also called off-aligned)), polygons, off-axis polygons, and the like, etc., or a randomly designed and aligned trench which is not geometrically based, but which can be based on the thermal profile of standard wafers which have been evaluated on the particular wafer carrier. The foregoing geometries can also be asymmetrical in form. Two or more geometries can be present.

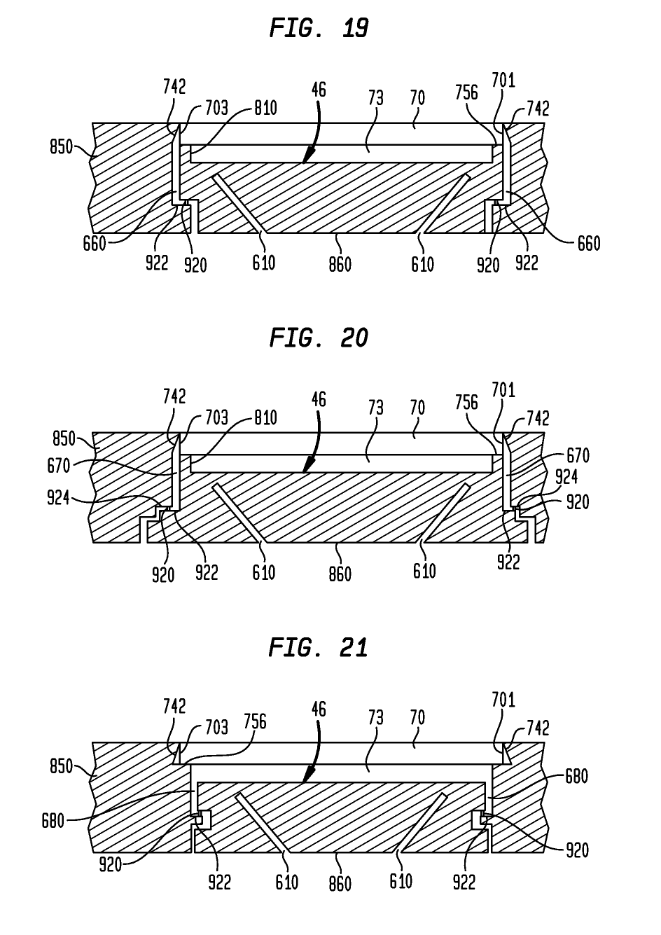

In some instances, a trench may extend entirely through the wafer carrier so that the trench is open to both the top and bottom of the wafer carrier. This can be accomplished, for example, in a manner shown in FIGS. 19-21.

Thus, in FIG. 19, trench 660 extends from wafer support surface 756 and exits through wafer carrier bottom 850. Supports 920 are disposed within the trench on a ledge 922 at spaced-apart locations around the pocket axis. Support 920 can be made of an insulator material or of a refractory material such as, for example, molybdenum, tungsten, niobium, tantalum, rhenium, as well as alloys (including other metals) thereof as discussed above. Alternatively, the trench 660 can be entirely filled with a solid material.

FIG. 20 shows another example of a trench 670 which extends from support surface 756 and exits through wafer carrier bottom 850. Supports 920 can be placed on ledges 922 and 924 at various points around the pocket axis.

FIG. 21 shows another example of a trench 680, which extends through the pocket floor surface 46 and which also extends through the wafer carrier bottom 860. Here again, supports 920 can be placed on ledge 922 at various points throughout the trench.

In each of FIGS. 16, 19, 20, and 21, vertical lines 701 and 703 schematically depict the edges of wafers disposed within the pockets of the carrier.

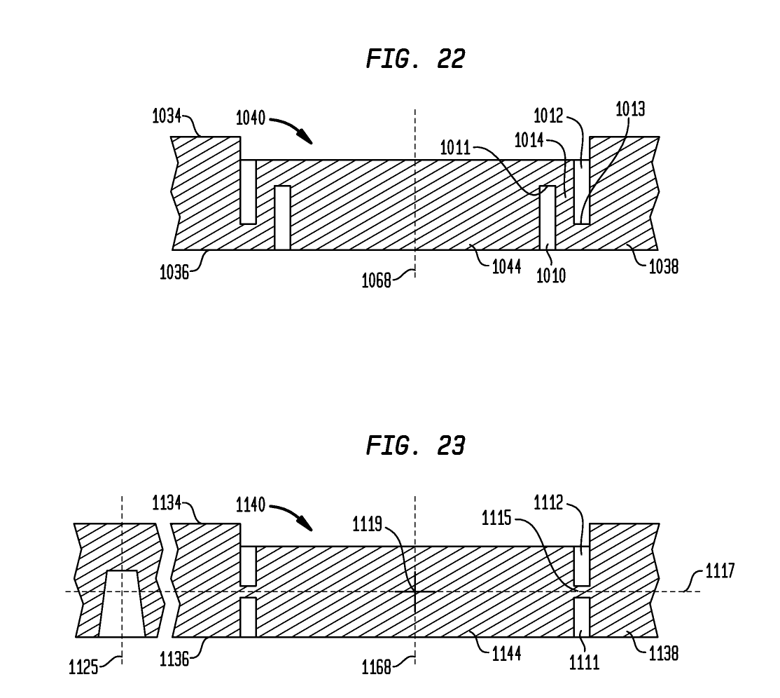

A wafer carrier according to a further embodiment of the invention (FIG. 22) includes a body having a main portion 1038 and a minor portion 1044 aligned with each pocket 1040. Each minor portion 1044 is formed integrally with the main portion 1038. An inner trench 1010 and an outer trench 1012 are associated with each pocket. Each of these is generally in the form of a right circular cylinder concentric with the vertical axis 1068 of the pocket. Outer trench 1012 is disposed near the periphery of pocket 1040 and extends around inner trench 1010. Inner trench 1010 is open to the bottom surface 1036 of the wafer carrier body and extends upwardly from the bottom surface to an end surface 1011. Outer trench 1012 is open to the top surface 1034 of the wafer carrier and extends downwardly to an end surface 1013. End surface 1013 is disposed below end surface 1011, so that the inner and outer trenches overlap with one another and cooperatively define a generally vertical, cylindrical wall 1014 between them. This arrangement provides a very effective thermal barrier between the minor portion and the main portion. Heat conduction between the minor portion 1044 and the main portion 1038 through the solid material of the wafer carrier must follow an elongated path, through the vertical extent of wall 1014. The same effect is obtained when the trenches are reversed, with the inner trench open to the top surface and the outer trench open to the bottom surface. Also, the same effect can be obtained where the inner trench, the outer trench, or both, are oblique trenches as, for example, generally conical trenches as seen in FIG. 14, or where one or both of the trenches is replaced by a thermal barrier other than a trench.

A wafer carrier according to a further embodiment of the invention (FIG. 23) also includes a body having a main portion 1138 and having a minor portion 1144 aligned with each pocket 1140, the minor portions 1144 being integral with the main portion 1138. A trench including an upper trench portion 1112 open to the top surface 1134 of the carrier and a lower trench portion 1111 open to the bottom surface 1136 of the carrier extends around the vertical axis 1168 of the pocket. Upper trench portion 1112 terminates above lower trench portion 1111, so that a support in the form of a relatively thin web 1115 of solid material integral with the minor portion 1144 and main portion 1138 extends across the trench between the upper and lower portions. Support 1115 is disposed at or near the horizontal plane 1117 which intercepts the center of mass 1119 of the minor portion 1144. Stated another way, the support 1115 is aligned in the vertical direction with the center of mass of the minor portion 1114. In operation, when the wafer carrier rotates at high speed about the central axis 1125 of the wafer carrier, the forces of acceleration or centrifugal forces on the minor portion 1144 will be directed outwardly, away from the central axis along plane 1117. Because the support 1115 is aligned with the plane of the acceleration forces, the support 1115 will not be subjected to bending. This is particularly desirable if the material of the wafer carrier body is substantially stronger in compression than in tension, inasmuch as bending loads can impose significant tension on part of the material. For example, graphite is about 3 to 4 times stronger in compression than in tension. Because support 1115 will not be subjected to appreciable bending loads due to the acceleration forces, a relatively thin support can be used. This reduces thermal conduction through the support and enhances the thermal isolation provided by the trench, which in turn enhances the thermal uniformity across the wafer and across the wafer carrier as a whole.

In the particular embodiment of FIG. 23, the support 1115 is depicted as a continuous web which extends entirely around the pocket axis 1168. However, the same principle of aligning the support with the vertical position of the minor portion center of mass can be applied where the support includes elements other than a continuous web, such as small isolated bridges extending between the minor portion 1144 and the main portion 1138 of the body.

In a further variant (not shown), upper trench portion 1112 can be covered by a cover element that desirably is formed from a material having substantially lower thermal conductivity that the material of the wafer carrier as a whole. The use of such a cover avoids any disruptions in gas flow which may be caused by a trench or a portion of a trench open to the top surface. Such a cover element can be used with any trench that is open to the top surface of the wafer carrier. For example, a peripheral trench 41 as shown in FIG. 3 can be formed as a single trench open to the top surface, or as a composite trench incorporating upper and lower trench portions as seen in FIG. 3, and a cover can be used to cover the opening of the trench in the top surface.

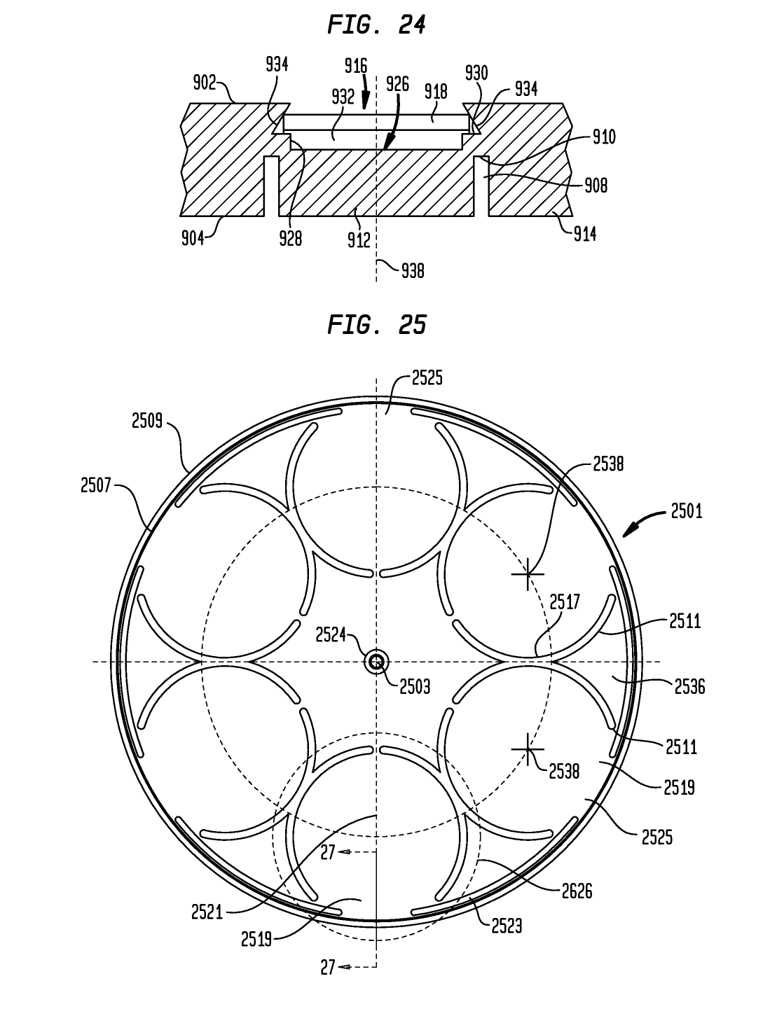

FIG. 24 shows another wafer carrier according to a further embodiment of the invention. In this embodiment, each pocket has an undercut peripheral wall 934. That is, peripheral wall 934 slopes outwardly, away from the central axis 938 of the pocket, in the downward direction away from the top surface 902 of the carrier. Each pocket also has a support surface 930 disposed above the floor surface 926 of the pocket. In operation, a wafer 918 sits in pocket 916, so that the wafer is supported above the floor surface on support surface 930 so as to form a gap 932 between the floor surface 926 and the wafer. When the carrier rotates about the axis of the carrier, acceleration forces will engage the edge of the wafer with the support surface and hold the wafer in the pocket, in engagement with the support surface. Support surface 930 may be in the form of a continuous rim encircling the pocket or else may be formed as a set of ledges disposed at spaced-apart locations around the circumference of the pocket. Also, the peripheral wall 934 of the pocket may be provided with a set of small projections (not shown) extending inwardly from the peripheral wall toward the central axis 938 of the pocket. As described in greater detail in commonly owned U.S. Published Patent Application No. 2010/0055318, the disclosure of which is incorporated by reference herein, such projections can hold the edge of the wafer slightly away from the peripheral wall of the pocket during operation.

The wafer carrier includes a body having a main portion 914 and a minor portion 912 aligned with each pocket 916. Each minor portion 912 is formed integrally with the main portion 914. A trench 908 is associated with each pocket and is generally in the form of a right circular cylinder concentric with the vertical axis 938 of the pocket. Trench 908 is disposed near or at the periphery of pocket 916. Trench 908 is open only to the bottom surface 904 of the wafer carrier body and extends upwardly from the bottom surface to an end surface 910. End surface 910 desirably is disposed below the level of the floor surface 926 of the pocket.

A wafer carrier according to a further embodiment of the invention is shown in FIGS. 25-27. As seen in bottom view (FIG. 25), the carrier has a body 2501 in the form of a generally circular disc having a vertical carrier central axis 2503. A fitting 2524 is provided at the carrier central axis for mounting the carrier to the spindle of a wafer treatment apparatus. The body has a bottom surface 2536, visible in FIG. 25, and a top surface 2534, seen in FIG. 27, which is a sectional view along line 27-27 in FIG. 25 and shows the body inverted. The peripheral surface 2507 of the body (FIG. 27) is cylindrical and coaxial with the carrier central axis 2503 (FIG. 25). A lip 2509 projects outwardly from peripheral surface 2507 adjacent top surface 2534. Lip 2509 is provided so that the carrier can be engaged readily by robotic carrier handling equipment (not shown).

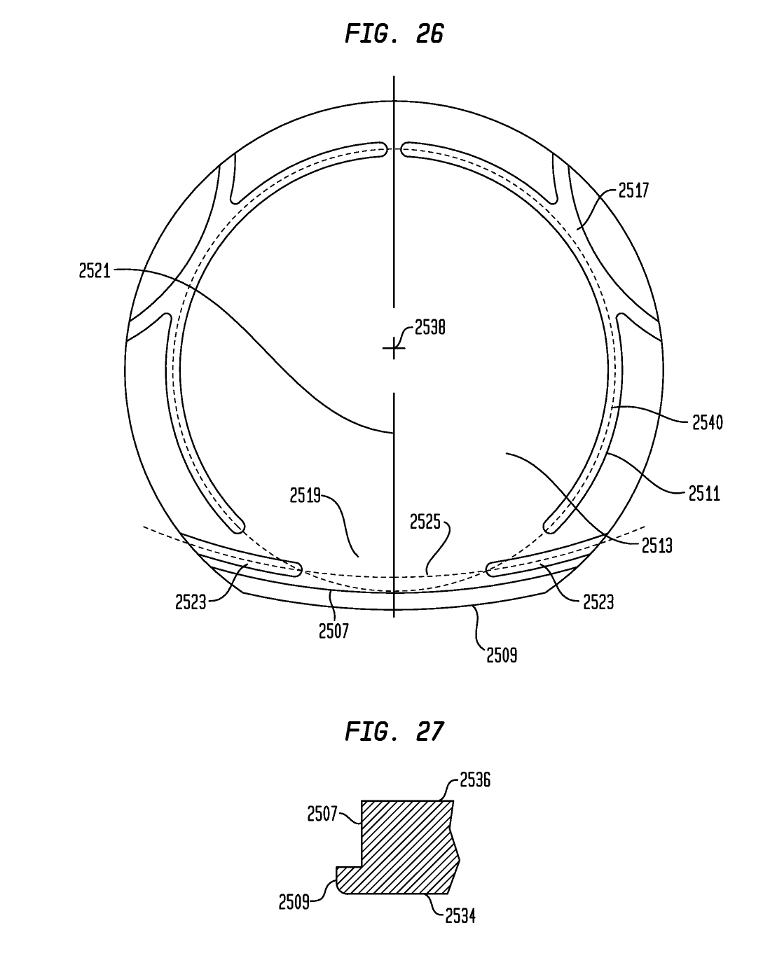

The carrier has pocket thermal control features in the form of trenches 2511 open to the bottom surface 2536. The pocket trenches 2511, and their relationships to the pockets on the top surface of the carrier, may be substantially as shown and described above with reference to FIG. 24. The outline of one pocket 2540 is shown in broken lines in FIG. 26, which is a detail view of the area indicated at 2626 in FIG. 25. Here again, each pocket 2540 is generally circular and defines a vertical pocket axis 2538. Each pocket trench 2511 in the bottom surface is concentric with the axis 2538 of the associated pocket in the top surface. Each pocket trench extends in alignment with the periphery of the associated pocket, so that the centerline of each pocket trench is coincident with the peripheral wall of the pocket. Thus, each pocket trench extends around a portion 2513 of the carrier body disposed beneath the associated pocket 2540. In the embodiment of FIGS. 25-27, all of the pockets 2540 are outboard pockets, disposed near the periphery of the carrier, with no other pocket intervening between these pockets and the periphery of the carrier.

As best seen in FIG. 25, the pocket trenches 2511 associated with mutually-adjacent pockets join one another at locations 2517 disposed between the pocket axes 2538 of the associated pockets. At these locations, the pocket trenches are substantially tangential to one another.

As seen in FIGS. 25 and 26, each pocket trench has a large interruption 2519 disposed along a radial line 2521 extending from the carrier central axis 2501 through the axis 2538 of the associated pocket. Stated another way, the large interruption 2519 in each pocket trench lies at the portion of the trench closest to the periphery of the carrier. Each pocket trench may have one or more smaller interruptions at other locations as well.

The carrier according to this embodiment also includes a peripheral thermal control feature 2523 in the form of a trench concentric with the carrier central axis 2503. This peripheral trench 2523 has interruptions 2525 that lie along the same radial lines 2521 as the large interruptions 2519 in the pocket trenches. Thus, the large interruptions 2519 in the pocket trenches 2511 are aligned with the interruptions 2525 in the peripheral trench. As best seen in FIG. 26, a straight path along radial line 2521 connecting the region 2513 beneath each outboard pocket and the peripheral surface 2507 does not pass through any thermal control feature or trench. As also seen in FIG. 26, the boundary of each outboard pocket in the top surface extends to or nearly to the peripheral surface 2507. This arrangement allows maximum space for pockets on the top surface of the carrier.

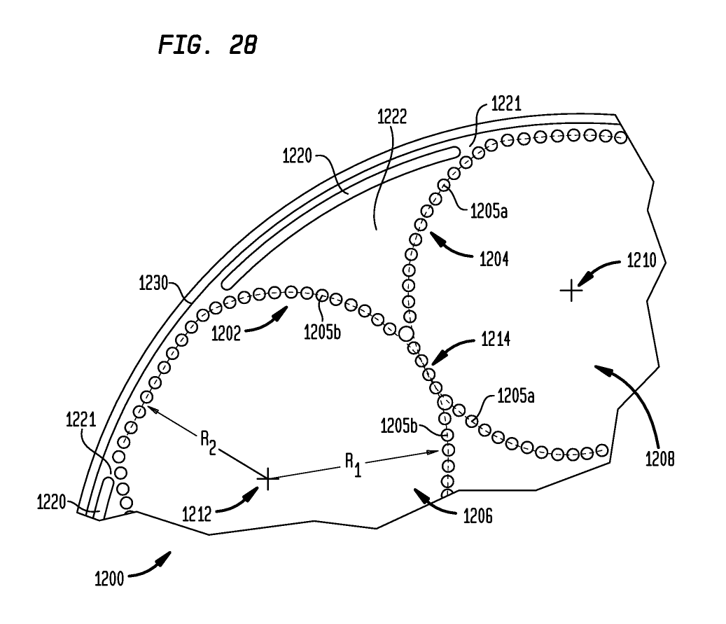

FIG. 28 shows a portion of an underside of a wafer carrier 1200 according to a further embodiment. In this embodiment, a pocket trench 1202 is comprised of individual holes. Each pocket trench extends completely around the central axis 1212 of the associated pocket and thus surrounds the region 1206 of the carrier disposed beneath the pocket. Similarly, trench 1204, comprised of individual holes, extends completely around the central axis 1210 of the adjacent pocket, and surrounds the region 1208 disposed beneath that pocket. Trenches 1202 and 1204 intersect to form a single trench 1214 at a location disposed between the axes 1210 and 1212 of the adjacent pockets.

In this embodiment, as in the embodiment of FIGS. 25-27, the carrier has a peripheral thermal control feature in the form of a trench 1220 having interruptions 1221. In this embodiment, the pocket trenches extend into the interruptions 1221 of the peripheral trench 1220. Peripheral trench 1220 sits just in from the peripheral surface 1230 of wafer carrier 1200. Trench 1220 helps to control the temperature of area 1222 of wafer carrier 1200. It will be appreciated that trenches 1202 and 1204, formed from separate holes, and 1220, formed as a single trench, can be formed as other trenches as provided for herein.

The centerline 1205a is shown for trench 1204; centerline 1205b is shown for trench 1202. In the embodiment depicted in FIG. 28, the centerline 1205b of trench 1202 lies at a first radius R₁ from the pocket axis 1212 in regions of the trench remote from the peripheral surface 1230 of the carrier, so that the centerline 1205b of the trench is approximately coincident with the peripheral wall of the pocket. In those regions of trench 1202 that are disposed near the peripheral surface of the carrier, within the interruption 1221 of the peripheral trench 1220, the pocket trench lies at a second radius R₂ from the pocket axis, R₂ being slightly less than R₁. Stated another way, trench 1202 is generally in the form of a circle concentric with pocket axis 1212, but having a slightly flattened portion near the periphery of the carrier. This assures that the pocket trench does not intersect the peripheral surface 1230 of the carrier.

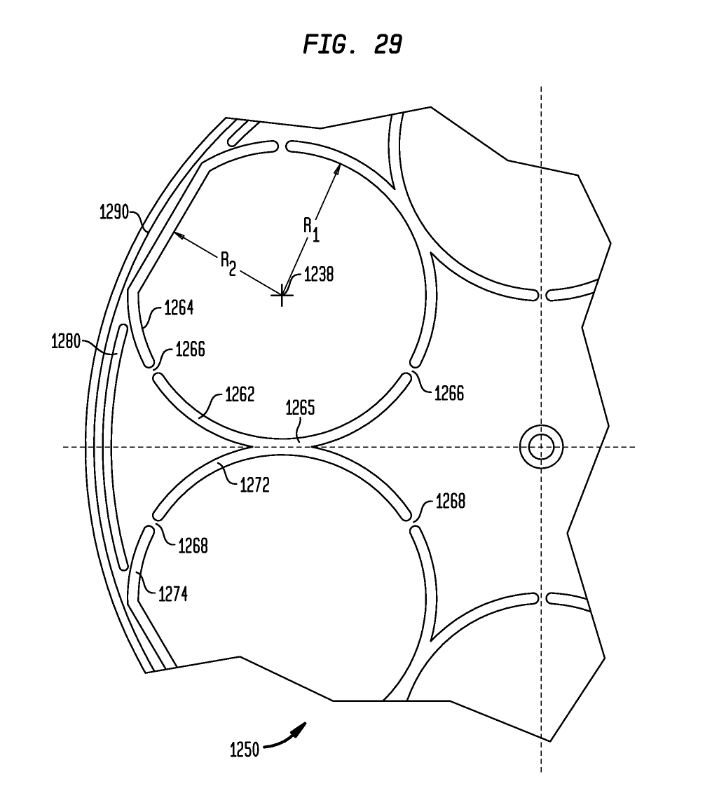

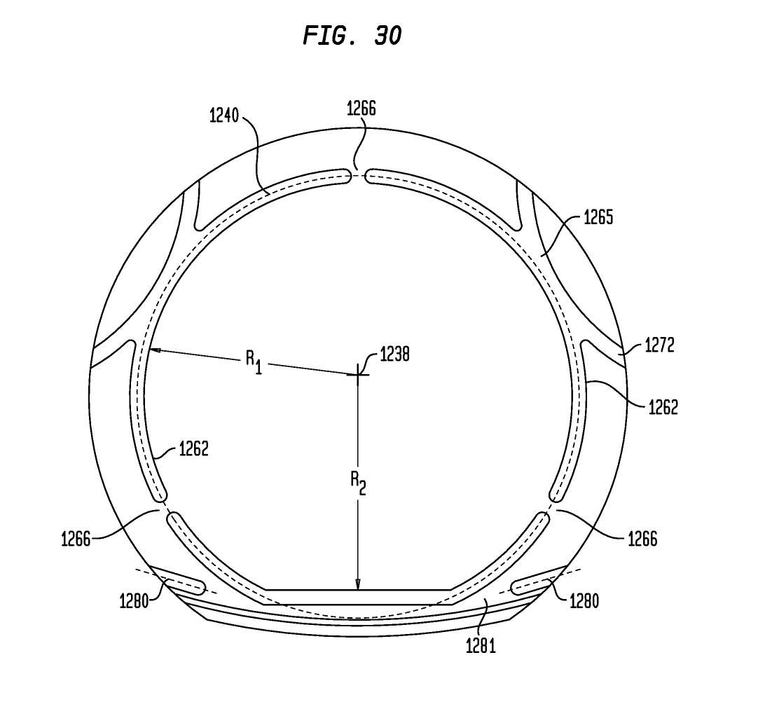

FIGS. 29 and 30 depict portions of an underside of a wafer carrier 1250 according to a further embodiment of the invention. In this embodiment, the pocket trenches 1262, 1272 (FIG. 29) are formed as substantially continuous trenches, with only minor interruptions 1266, 1268 for structural strength. Here again, each pocket trench extends around a region of the carrier disposed beneath a pocket in the top surface. As in the embodiment of FIG. 28, the pocket trenches 1262 and 1272 are generally circular and concentric with the pocket axes of the associated pockets, but have flattened portions adjacent the periphery of the carrier.

As best seen in FIG. 30, in regions of the trench 1262 remote from the periphery of the carrier, the trench lies at a first radius R₁ from the central axis 1238 of the associated pocket so that the centerline of the trench is substantially coincident with the peripheral wall 1240 of the associated pocket, seen in broken lines in FIG. 30. In a region of the trench adjacent the periphery of the carrier, the pocket trench lies at a lesser radius R₂ from the center of the pocket. In this embodiment as well, the pocket trench extends into interruptions 1281 in the peripheral thermal control feature or trench 1280. Trenches 1262 and 1272 meet to form a single trench 1265 at locations between the axes of adjacent pockets. It will be appreciated that trenches 1262, 1264, 1272, 1274, and 1280 can be formed as other trenches as provided for herein.

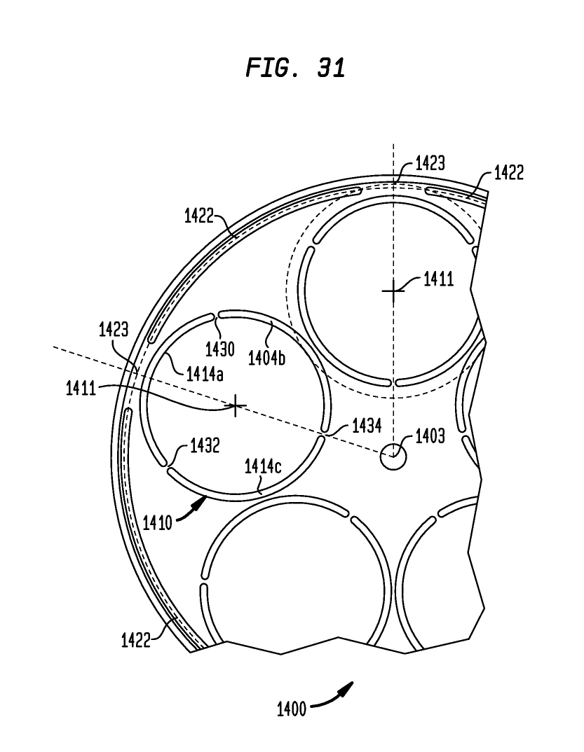

FIG. 31 shows a portion of an underside of a wafer carrier 1400 according to yet another embodiment. In this embodiment, pocket trench 1410 is substantially continuous trench in the form of a circle concentric with the axis 1411 of the associated pocket, with only minor interruptions for structural strength. Thus, pocket trench 1410 includes segments 1414a, 1414b, and 1414c, separated by minor interruptions 1430, 1432, and 1434. Here again, the carrier includes a peripheral thermal control feature in the form of a trench 1422 having interruptions 1423 aligned with the radial lines such extending from the carrier central axis 1403 through the central axis 1411 of each outboard pocket. In this embodiment, the outboard pockets are far enough from the periphery of the carrier that the pocket trenches do not intercept the peripheral surface of the carrier.

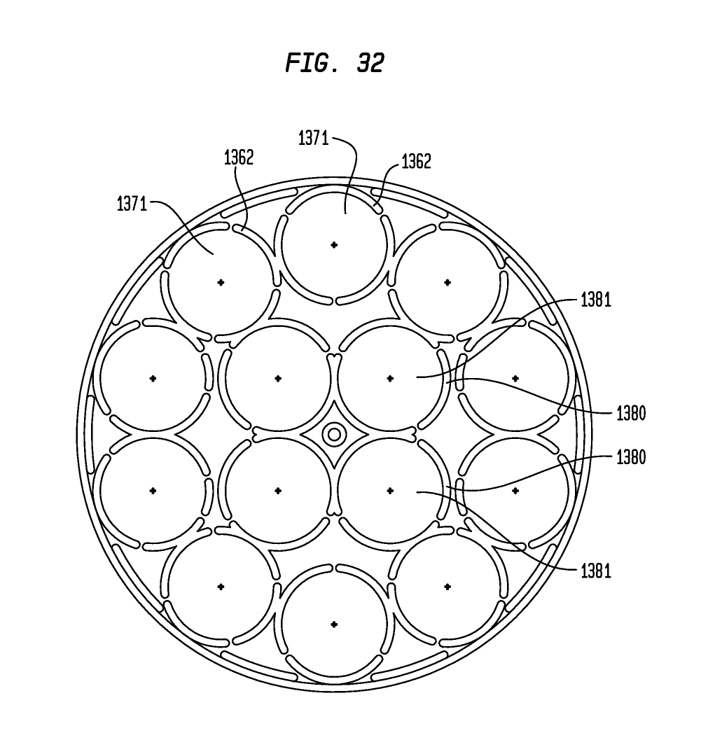

In each of the embodiments discussed above with reference to FIGS. 25-31, all of the pockets are outboard pockets, lying adjacent the periphery of the carrier. However, in variants of these embodiments, using a larger carrier or smaller pockets, additional pockets may be disposed between the outboard pockets and the carrier central axis. These additional pockets can be provided with pocket trenches as well. For example, the carrier of FIG. 32 includes outboard pocket trenches 1362 extending around regions 1371 of the carrier disposed beneath outboard pockets (not shown in the bottom view of FIG. 32). The carrier also has inboard pocket trenches 1380 that extend around portions 1381 of the carrier body disposed beneath inboard pockets (not shown).

The various trench geometries can be combined with one another and varied. For example, any of the trenches discussed above can be open to the top of the carrier, to the bottom of the carrier or both. Also, the other features discussed above with respect to individual embodiments can be combined with one another. For example, any of the pockets optionally can be provided with locks as discussed with reference to FIGS. 1-5. The peripheral thermal control feature need not be a trench, but can be a gap that does not extend to the top or bottom surface of the carrier, or a pair of abutting surfaces between solid elements as used in thermal barrier 48 (FIG. 3).

Another type of wafer carrier useful in the present invention is a planetary wafer carrier described in copending U.S. patent application Serial No. 13/153,679, filed Jun. 6, 2011, entitled “Multi-Wafer Rotating Disc Reactor With Inertial Planetary Drive,” the contents of which are hereby incorporated herein by reference.

As these and other variations and combinations of the features described above can be utilized, the foregoing description of the preferred embodiments should be taken as illustrating, rather than limiting, the scope of the invention.

1. A wafer carrier comprising a body having oppositely-facing top and bottom surfaces extending in horizontal directions and a plurality of pockets open to the top surface, each such pocket being adapted to hold a wafer with a top surface of the wafer exposed at the top surface of the body, the carrier defining a vertical direction perpendicular to the horizontal directions, the body including one or more thermal control features, each said feature extending along a defining surface within the body and having thermal conductivity in directions normal to its defining surface different than a thermal conductivity of adjacent portions of the body, at least one said feature being an oblique feature having at least a part of its defining surface oblique to the vertical direction.

2. The wafer carrier as claimed in claim 1 wherein each said feature has dimensions parallel to the defining surface of that feature greater than dimensions of the feature normal to the defining surface of that feature.

3. The wafer carrier as claimed in claim 2 wherein at least one of the features includes a trench intersecting at least one of the top and bottom surfaces.

4. The wafer carrier as claimed in claim 1 wherein at least one of the features has a thermal conductivity lower than the thermal conductivity of adjacent portions of the body.

5. The wafer carrier as claimed in claim 4 wherein at least one of the features includes a gap which is unfilled by solid or liquid material.

6. The wafer carrier as claimed in claim 4 wherein the body includes a plurality of separate solid portions and at least some of said features include boundaries between at least some of the portions.

7. The wafer carrier as claimed in claim 1 wherein at least one said pocket has a central axis extending in the vertical direction and at least one said feature associated with the pocket disposed adjacent the pocket and extending at least partially around the central axis of the pocket.

8. The wafer carrier as claimed in claim 7 wherein at least one said pocket has at least one said oblique feature associated with the pocket substantially in the form of a surface of revolution about the central axis of the pocket.

9. The wafer carrier as claimed in claim 7 wherein at least one said pocket has an inner one of said features associated with the pocket and extending at least partially around the central axis of the pocket and an outer one of said features extending at least partially around the pocket outside of the inner one of said features.

10. The wafer carrier as claimed in claim 9 wherein the inner one of said features is an oblique feature substantially in the form of a surface of revolution about the central axis of the pocket.

11. The wafer carrier as claimed in claim 1 wherein at least one of said features is a vertical feature having a defining surface which is substantially vertical.

12. The wafer carrier as claimed in claim 1 wherein at least one of said features intersects the top surface of the body within at least one of said pockets.

13. The wafer carrier as claimed in claim 12 wherein each said pocket has a wafer support adjacent the periphery of the pocket and at least one of said features intersects the wafer support of at least one of said pockets.

14. The wafer carrier as claimed in claim 11 wherein the pocket has a wafer support adjacent the periphery of the pocket and the outer one of said features intersects the wafer support.

15. A wafer carrier comprising a body having oppositely-facing top and bottom surfaces extending in horizontal directions, the body having a vertical direction perpendicular to the horizontal directions and a plurality of pockets open to the top surface, each such pocket being adapted to hold a wafer with a top surface of the wafer exposed at the top surface of the body, the body including one or more trenches, each said trench intersecting at least one of the top and bottom surfaces of the body, the trenches having thermal conductivity different from a thermal conductivity of the body.

16. The wafer carrier as claimed in claim 15 wherein the body is a unitary body.

17. The wafer carrier as claimed in claim 16 wherein each pocket has a central axis and at least one pocket has a peripheral trench extending at least partially around the central axis of the pocket adjacent the periphery of the pocket.

18. The wafer carrier as claimed in claim 17 wherein each said peripheral trench extends entirely around the central axis of the pocket.

19. The wafer carrier as claimed in claim 15 wherein each said trench has a thermal conductivity lower than the thermal conductivity of the body whereby each said trench acts as a barrier to thermal conduction within the body.

20. The wafer carrier of claim 19 wherein the trenches are at least partially devoid of solid or liquid material.

21. The wafer carrier of claim 15 wherein at least one said trench is a vertical trench having a depth direction which is substantially vertical.

22. The wafer carrier of claim 15 wherein at least one said trench is an oblique trench having a depth direction oblique to the vertical direction.

23. The wafer carrier of claim 15 wherein at least one said trench intersects the bottom surface of the body but does not intersect the top surface of the body.

24. The wafer carrier of claim 15 wherein at least one said trench intersects the top surface of the body but does not intersect the bottom surface of the body.

25. The wafer carrier of claim 15 wherein at least one said trench is a through trench which intersects both the top and bottom surfaces of the body.

26. The wafer carrier of claim 25 wherein at least one said through trench includes solid supports extending across the trench and connecting opposing walls of the trench to one another but not filling the trench.

27. The wafer carrier of claim 15 wherein each said pocket has a vertical central axis, and the trenches include an inner trench extending at least partially around the central axis of one said pocket and an outer trench extending at least partially around the inner trench.

28. The wafer carrier of claim 27 wherein one of the inner and outer trenches intersects the top surface of the body but not the bottom surface and the other one of the inner and outer trenches intersects the bottom surface of the body but not the top surface.

29. The wafer carrier of claim 15 at least one of said trenches extends in horizontal directions so that an intersection of the trench with the top or bottom surface of the body is a geometrical figure selected from circles, ellipses, off-axis ellipses, serpentines, spirals, clothoides, parabolas, and polygons.

30. A wafer carrier comprising a body having oppositely-facing top and bottom surfaces extending in horizontal directions, a carrier central axis, a peripheral region, and a pocket region between the central axis with a plurality of pockets open to the top surface in the pocket region, each such pocket being adapted to hold a wafer with a top surface of the wafer exposed at the top surface of the body, the body having a peripheral thermal control feature extending around the pocket region between the pocket region and the peripheral region, the peripheral thermal control feature having lower thermal conductivity than adjacent portions of the body so that the peripheral thermal control feature reduces thermal conduction between the pocket region and the peripheral region.

31. A wafer carrier comprising a body having oppositely-facing top and bottom surfaces extending in horizontal directions, a carrier central axis, a peripheral surface, and a plurality of pockets open to the top surface between the central axis and the peripheral surface, each such pocket being adapted to hold a wafer with a top surface of the wafer exposed at the top surface of the body, the body having a plurality of pocket thermal control features, each pocket having a pocket thermal control feature associated with the pocket extending at least partially around a portion of the body disposed beneath the pocket, the body further having a peripheral thermal control feature extending around the carrier adjacent the peripheral surface, the thermal control features having lower thermal conductivity than adjacent portions of the body so that the thermal control features suppress thermal conduction in the horizontal directions.

32. The wafer carrier as claimed in claim 31 wherein the at least some of the pockets are outboard pockets disposed adjacent the peripheral surface, and wherein the peripheral thermal control feature has interruptions adjacent the outboard pockets.

33. The wafer carrier as claimed in claim 32 wherein the pocket thermal control feature associated with each outboard pocket has an outboard interruption aligned with one of the interruptions in the peripheral thermal control feature.

34. The wafer carrier as claimed in claim 33 wherein the wafer carrier is circular and has a carrier central axis, each pocket is circular and has a vertical central axis, and each pocket thermal control feature is substantially in the form of an arc coaxial with the associated pocket, and wherein the interruptions in the peripheral thermal control feature and the outboard interruptions of the pocket thermal control features are aligned with radii of the carrier extending from the carrier central axis through the central axes of the outboard pockets.

35. The wafer carrier as claimed in claim 32 wherein the pocket thermal control feature associated with each outboard pocket has an outermost section bridging an interruption in the peripheral thermal control feature.

36. The wafer carrier as claimed in claim 31 wherein the thermal control features are trenches.

37. The wafer carrier as claimed in claim 36 wherein the wafer carrier is circular and has a carrier central axis, each pocket is circular and has a vertical central axis, and each pocket thermal control feature is substantially in the form of an arcuate trench coaxial with the associated pocket, and wherein the arcuate trenches associated with at least one pair of mutually-adjacent pockets join one another at locations between the central axes of the mutually-adjacent pockets.

38. Wafer processing apparatus comprising:
(a) a reaction chamber;
(b) a spindle mounted within the reaction chamber and rotatable about central axis;
(c) a wafer carrier according to any one of claims 1, 15, 30, and 31 mounted to the spindle for rotation therewith;
(d) a gas distribution element mounted to the chamber above the wafer carrier and arranged to direct gasses downwardly onto the wafer carrier; and
(e) a heater mounted within the chamber below the carrier.

39. A method of processing wafers comprising:
(a) retaining the wafers in the pockets of a wafer carrier according to any one of the claims 1, 15, 30 and 31 so that top surfaces of the wafers are exposed at the top surface of the carrier; and
(b) while the wafers are so retained, directing gasses downwardly onto the top surfaces of the wafers and carrier while heating the carrier from below.
